(19) United States
(12) Patent Application Publication
(10) Pub. No.: US 2014/0034127 A1
(43) Pub. Date: Feb. 6, 2014

(54) SURFACE-MOUNTABLE LENS CRADLES AND INTERCONNECTION STRUCTURES FOR CONCENTRATOR-TYPE PHOTOVOLTAIC DEVICES

(71) Applicant: SEMPRIUS, INC., Durham, NC (US)

(72) Inventors: Matthew Meitl, Durham, NC (US); Christopher Bower, Raleigh, NC (US); Baron Kendrick, Cary, NC (US); Bruce Furman, Saratoga Springs, NY (US)

(73) Assignee: Semprius, Inc., Durham, NC (US)

(21) Appl. No.: 13/835,851

(22) Filed: Mar. 15, 2013

Related U.S. Application Data
(60) Provisional application No. 61/677,892, filed on Jul. 31, 2012.

(51) Int. Cl. H01L 31/052

(52) U.S. Cl. CPC H01L 31/0524
USPC 136/259; 438/65

(57) ABSTRACT

A concentrator-type photovoltaic (CPV) receiver includes a solar cell on a substrate. The solar cell includes a light receiving surface having a conductive terminal thereon. A conductive lens support frame is mounted on the substrate and includes an opening therein that exposes the light receiving surface of the solar cell. A lens element is provided on the support frame opposite the light receiving surface of the solar cell. The support frame is electrically connected to the conductive terminal on the light receiving surface and an electrical node on the substrate. The support frame also supports and self-aligns the lens element with the light receiving surface to concentrate incident light thereon. Related fabrication processes are also discussed.

### RELATED APPLICATIONS

The present application claims priority from U.S. Provisional Patent Application No. U.S. Provisional Patent Application No. 61/677,892 entitled “Surface-Mountable Lens Cradles And Interconnection Structures For Concentrator-Type Photovoltaic Devices” filed on Jul. 31, 2012, the disclosure of which is incorporated by reference herein in its entirety. The present application is also related to U.S. Provisional Patent Application No. 61/683,958 entitled “Surface Mountable Solar Receiver with Integrated Through Substrate Interconnect and Optical Element Cradle” filed on Aug. 16, 2012, the disclosure of which is incorporated by reference herein in its entirety.

### FIELD

The present invention relates to photovoltaic devices and methods of forming same and, more particularly, to concentrator-type photovoltaic devices and methods of fabricating the same.

### BACKGROUND

Concentrator Photovoltaics (CPV) is an increasingly promising technology for renewable electricity generation in sunny environments. CPV uses relatively inexpensive, efficient optics to concentrate sunlight onto solar cells, thereby reducing the cost requirements of the semiconductor material and enabling the economic use of the most efficient cells, for example multi-junction solar cells. This high efficiency at reduced costs, in combination with other aspects, makes CPV among the most economical renewable solar electricity technology in sunny climates and geographic regions.

CPV module designs that use small solar cells (for example, cells that are smaller than about 4 mm²) may benefit significantly because of the ease of energy extraction from such cells. The superior energy extraction characteristics apply to both usable electrical energy and waste heat, potentially allowing a better performance-to-cost ratio than CPV module designs that use larger cells. However, the production of small solar cell designs may introduce technical challenges, for example, the interconnection of arrays with high part-count and the demanding spatial tolerances between small cells and optical components.

### SUMMARY

According to some embodiments, a concentrator-type photovoltaic receiver includes a conductive lens support frame that provides electrical connection between an electrical node on a backplane or other supporting substrate and a conductive terminal of a photovoltaic cell having a surface mounted on the substrate. The conductive terminal is on a surface of the photovoltaic cell opposite to the surface thereof on the backplane or supporting substrate. The frame includes features for supporting and aligning a secondary optical element over the photovoltaic cell such that light is concentrated thereon.

According to further embodiments, a concentrator-type photovoltaic (CPV) receiver includes a solar cell on a backplane substrate. The solar cell includes a light receiving surface having a conductive terminal thereon opposite the mounting surface. A conductive lens support frame is provided on the substrate and extending on the solar cell. The support frame includes an opening therein that exposes the light receiving surface of said solar cell. A lens element is provided on the support frame opposite the light receiving surface of the solar cell. The support frame is electrically connected to the conductive terminal on the light receiving surface and to an electrical node on the substrate. The support frame also supports and self-aligns the lens element with the light receiving surface to concentrate incident light thereon. The support frame may be provided on the substrate in a surface mount operation.

In some embodiments, a solder connection may be provided between the support frame and the conductive terminal and/or the substrate. The support frame may be configured to be self-aligned by reflow of the solder connection to align the lens element with the solar cell. The reflow of the solder connection may provide spatial registration between features of the support frame, features on the backplane or supporting substrate, and features on the solar cell.

In some embodiments, the support frame may include features for supporting and self-aligning a spherical secondary optical element with good spatial registration between the lens element and the solar cell.

In some embodiments, the frame may be a conductive metal frame.

In some embodiments, the frame may be a printed wiring board including conductive traces thereon.

In some embodiments, the support frame may be a portion of the backplane substrate including conductive traces thereon.

In some embodiments, the conductive terminal on the light receiving surface may be a first conductive terminal, and a conductive lead frame may electrically connect a second conductive terminal on a surface of the solar cell opposite the light receiving surface to the substrate.

In some embodiments, the support frame may be a multi-layer printed wiring board interposer including the solar cell on a surface thereof, and the printed wiring board interposer may extends between the solar cell and the backplane substrate.

In some embodiments, the solar cell may include a conductive through-wafer via or through-substrate interconnect having insulated sidewalls extending therein from the mounting surface on the substrate toward the light receiving surface. The via may electrically connect the conductive terminal on the light receiving surface to the electrical node on the substrate.

According to still further embodiments, concentrator-type photovoltaic (CPV) device includes a solar cell on a substrate. The solar cell includes a light receiving surface and a conductive terminal. A conductive lens support frame is provided on the solar cell. The lens support frame exposes the light receiving surface and electrically connects the conductive terminal to a contact on the substrate. A lens element is positioned over the light receiving surface by the support frame.

In some embodiments, the lens support frame may include an opening therein that exposes the light receiving surface.

In some embodiments, the support frame may align the lens element with a center of the light receiving surface.

In some embodiments, the light receiving surface may have an area of about 4 mm² or less.

In some embodiments, the lens element may be a spherical lens element.

In some embodiments, the lens element may extend at least partially into the opening.

In some embodiments, the support frame may be a conductive metal frame.

In some embodiments, the support frame may be a printed wiring board including conductive traces thereon.

In some embodiments, the support frame may be a portion of the backplane substrate including conductive traces thereon.

According to yet further embodiments, a process for fabricating a concentrator-type photovoltaic receiver on a backplane or support substrate includes mounting a concentrator photovoltaic cell to a surface of the backplane or supporting substrate, mounting a conductive lens support frame onto the cell such that a conductive terminal of the cell is electrically connected to an electrical node on the backplane or supporting substrate by the support frame, and placing a lens element on the support frame such that the lens element is supported and aligned by the support frame.

In some embodiments, the support frame may be mounted using a solder connection between the support frame and the conductive terminal and/or between the support frame and the electrical node on the substrate. The solder connection may be reflowed to align the opening in the support frame (and/or the lens element thereon) with the light receiving surface of the solar cell.

In some embodiments, the lens element may be a spherical lens element, and the support frame may include features that supports and self-align the spherical lens element.

In some embodiments, the support frame may be a conductive metal frame, and may be surface-mounted onto the light receiving surface of the solar cell to contact the conductive terminal thereon.

In some embodiments, the support frame may be a printed wiring board including conductive traces thereon, and may be surface-mounted onto the light receiving surface of the solar cell to contact the conductive terminal thereon.

In some embodiments, the support frame may be a multi-layer printed wiring board interposer. The solar cell may be mounted on a surface of the printed wiring board interposer, and the printed wiring board interposer may be surface-mounted on the surface of the substrate.

According to still further embodiments, a process for assembling an array of photovoltaic receivers on a backplane or support substrate includes surface mounting concentrator photovoltaic cells to said backplane or support substrate, surface mounting a conductive frame onto said cells that bridges the top terminal of said cells to an electrical node on said backplane or support substrate, performing solder reflow, and placing or attaching a spherical secondary optical element with good spatial registration to said cell and said backplane or support substrate using features included in the conductive frame.

Other methods, systems, and/or devices according to some embodiments will become apparent to one with skill in the art upon review of the following drawings and detailed description. It is intended that all such additional embodiments, in addition to any and all combinations of the above embodiments, be included within this description, be within the scope of the invention, and be protected by the accompanying claims.

### BRIEF DESCRIPTION OF THE DRAWINGS

The above and other features and advantages of the present invention will become evident upon review of the following summarized and detailed descriptions in conjunction with the accompanying drawings:

FIG. 1A is a cross-sectional view illustrating a surface mountable lead frame lens cradle interconnection structure in accordance with some embodiments of the present invention.

FIGS. 1B, 1C, and 1D are perspective, plan, and side views of the interconnection structure of FIG. 1A, respectively.

FIG. 1E is an enlarged perspective view of the interconnection structure of FIG. 1A.

FIG. 1F is a plan view illustrating an array of CPVs including the interconnection structure of FIG. 1A.

FIG. 2 is a cross-sectional view illustrating a printed wiring board lead frame lens cradle interconnection structure in accordance with some embodiments of the present invention.

FIG. 3 is a cross-sectional view illustrating a thermal interface material interconnection structure in accordance with some embodiments of the present invention.

FIG. 4 is a cross-sectional view illustrating a surface mount lead frame interconnection structure in accordance with some embodiments of the present invention.

FIG. 5 is a cross-sectional view illustrating a multi-level printed wiring board interposer interconnection structure in accordance with some embodiments of the present invention.

FIG. 6 is a cross-sectional view illustrating a surface mountable lead frame lens cradle interconnection structure including a through-substrate via in accordance with some embodiments of the present invention.

FIG. 7 is a cross-sectional view illustrating a printed wiring board lead frame lens cradle interconnection structure including a through-substrate via in accordance with some embodiments of the present invention.

### DETAILED DESCRIPTION OF EMBODIMENTS

In order to benefit from advantages provided by smaller solar cells (e.g., cells having a surface area of about 4 mm² or less and a thickness of less than about 1 mm), manufacturing processes and designs may be needed to address the associated technical challenges and costs, namely the interconnection of arrays with high part-count and the demanding spatial tolerances between small cells and optical components in rapid and inexpensive ways.

Embodiments of the present invention provide devices and manufacturing processes that allow for rapid and inexpensive electrical interconnection of small cells onto a CPV receiver array (or backplane) and simultaneously provide for precise alignment and attachment of secondary optical elements to the cells. Some embodiments may be used in CPV modules that use spherical ball lenses as secondary optical elements.

In particular, some embodiments of the present invention include conductive “cradle” structures that provide both an electrical connection between a backplane and a solar cell surface mounted thereon, and a mechanical guide for a ball lens and/or other lens types to gravitationally self-align to the solar cell. As such, conductive lens support and interconnection structures or frames according to some embodiments as described herein not only support/align a lens element with a light receiving surface of a solar cell, but also electrically connect the solar cell to a backplane or other support substrate. In other words, a conductive lens support interconnection structure as described herein simultaneously provides both a mechanical and an electrical function for the solar cell on which it is mounted or otherwise affixed.

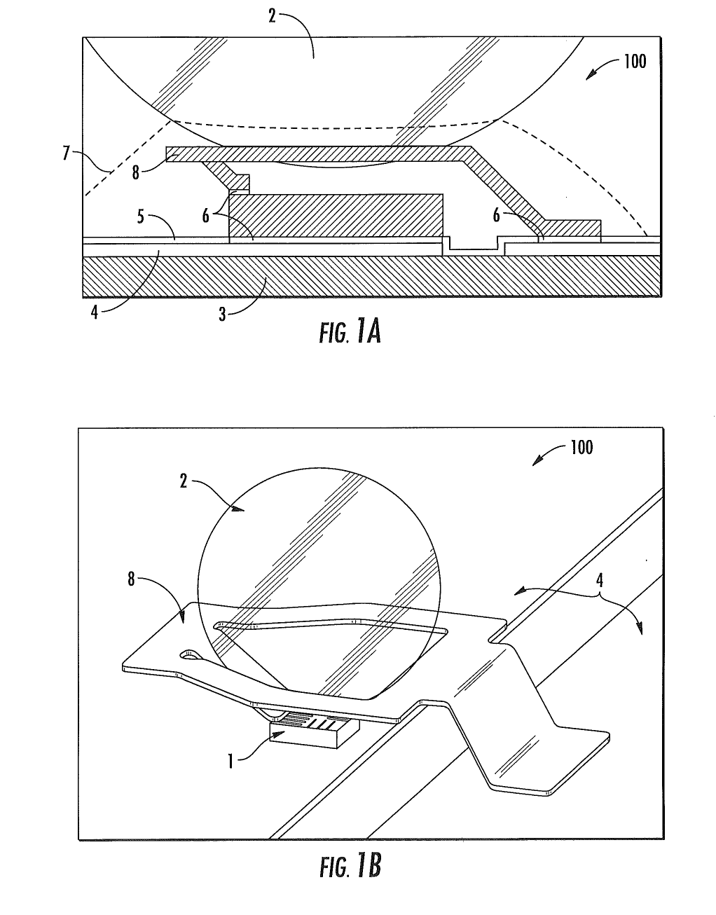

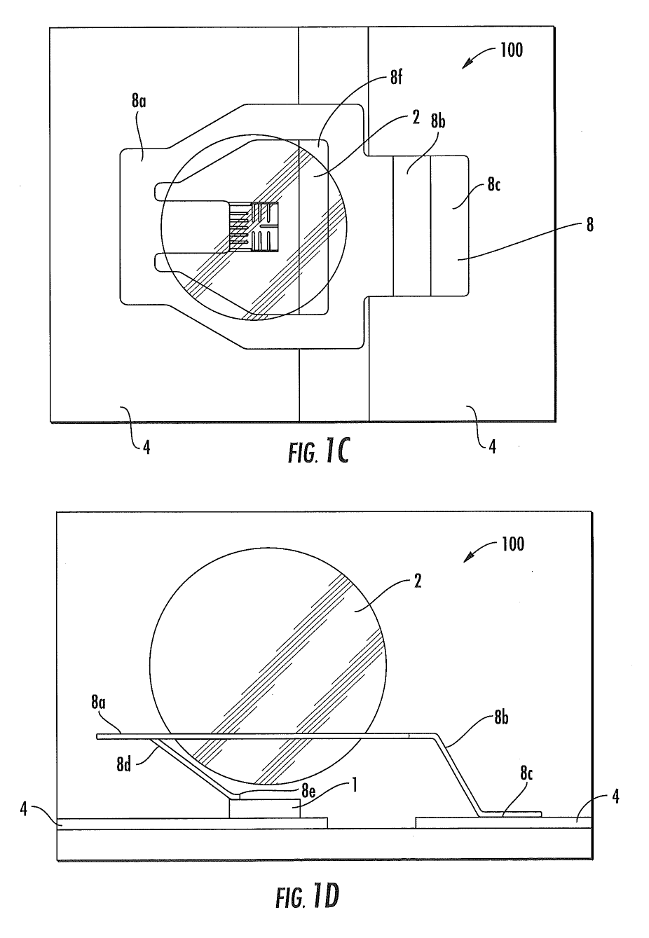

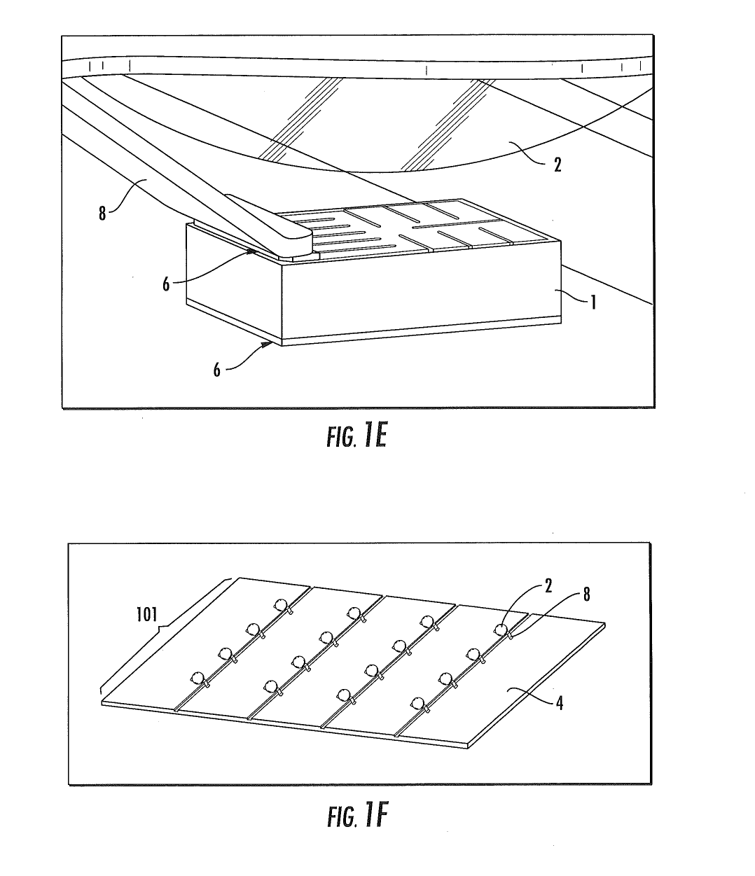

FIG. 1A illustrates a CPV device 100 including a lens cradle (also referred to herein as a lens support structure or frame) 8 in the form of a conductive lead frame, for example, a metal lead frame formed by one or more of photolithography, etching, electroplating, and stamping. In particular, FIG. 1A illustrates a concentrator solar cell 1, a spherical or ball lens 2 (illustrated as a glass bead), and a backplane 3 including metal (for example, copper) traces 4 on the backplane 3. A solder mask 5 may be used in some embodiments to guide the spatial positions of components during reflow of a solder connection (illustrated more generally as a cell contact 6) to the solar cell 1. An optically transparent material 7 may encapsulate the cell 1 and bond the ball lens 2 to the cell 1 and related components. A surface mountable lead frame lens cradle 8 supports and self-aligns the ball lens 2 with the light receiving surface of the solar cell 1, and also serves as an electrical interconnection apparatus that provides an electrical connection between the backplane 3 and the cell contact 6 on the surface of the cell 1 opposite the backplane 3. The ball lens 2 may be a secondary lens element, and a primary lens element (for example, a Fresnel lens, a plano-convex lens, a double-convex lens, a crossed panoptic lens, and/or arrays thereof) may be positioned over the secondary lens element to direct incident light thereto.

While illustrated primarily herein as a spherical lens element or ball lens 2, it will be understood that lens elements of other shapes may be used in any of the embodiments of the present invention described herein. Also, the shape of the conductive lens support frames described herein may depend on the shape of the lens element 2 and/or the shape of the light receiving surface of the solar cell 1, and may include any shape that positions and aligns the lens element 2 with the light receiving surface. For example, the lens support frame may have a polygonal or ellipsoidal shape, and may include a polygonal- or ellipsoidal-shaped cavity or opening therein.

FIGS. 1B, 1C, and 1D illustrate perspective, plan, and side views of the CPV device 100 of FIG. 1A, respectively. As shown in FIGS. 1B, 1C, and 1D, the conductive lens support frame 8 includes a metal frame or periphery 8a that defines a polygonal opening or cavity 8f therein, which exposes the light receiving surface of the solar cell 1 and suspends the lens 2 over the light receiving surface. The support frame 8 also includes “legs” 8b and 8d, which are elongated members that extend from the metal frame 8a and provide electrical contact with the backplane 3 and the solar cell 1 via “foot” portions 8c and 8e, respectively. One or more of the members 8a-8e of the support frame 8 may be formed from a single conductive layer, or may be separately formed and assembled. FIG. 1E illustrates the solder connections between the lens support frame 8 and the solar cell 1, and between the solar cell 1 and the backplane 3, in greater detail. In some embodiments, the support frame 8 is configured to be self-aligned by solder reflow to provide spatial registration between features of the frame 8, features on the backplane 3, and features on the solar cell 1. FIG. 1F is a plan view illustrating an array 101 of CPV devices 100 including the interconnection structure of FIG. 1A arranged on a common backplane 3.

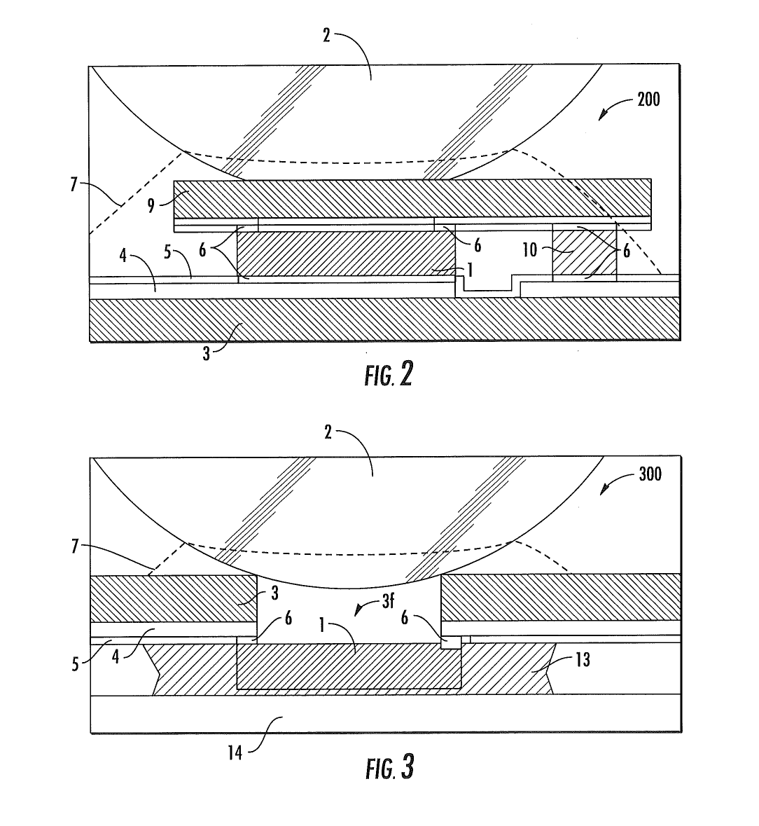

FIG. 2 illustrates a CPV device 200 including a conductive lens cradle or support frame 9 in the form of a printed wiring board, for example, a lead frame including conductive traces and made from metal formed by one or more of photolithography, etching, electroplating, pick-and-place, laser cutting, drilling, and punching. In particular, FIG. 2 illustrates a concentrator solar cell 1, a spherical or ball lens 2 (illustrated as a glass bead), and a backplane 3 including metal (for example, copper) traces 4 on the backplane 3. A solder mask 5 may be used in some embodiments to guide the spatial positions of components during reflow of a solder connection (illustrated more generally as a cell contact 6) to the solar cell 1. An optically transparent material 7 may encapsulate the cell 1 and bond the ball lens 2 to the cell 1 and related components. A surface mountable printed wiring board lead frame lens cradle 9 supports and self-aligns the ball (or other-shaped) lens 2 with the light receiving surface of the solar cell 1. A conductive stud 10 electrically connects the printed wiring board lead frame 9 to the traces 4 on the backplane 3. As such, the lens cradle 9 (along with the conductive stud 10) also serves as a conductive interconnection apparatus that provides an electrical connection between the backplane 3 and the cell contact 6 on the surface of the cell 1 opposite the backplane 3.

The shape of the printed wiring board lens support frame 9 and/or the conductive traces thereon may depend on the shape of the lens element 2 and/or the shape of the light receiving surface of the solar cell 1, and may include any shape that supports and aligns the lens element 2 with the light receiving surface, including polygonal or ellipsoidal shapes. The printed wiring board lens support frame 9 also defines a polygonal- or ellipsoidal-shaped cavity or depression therein, which may also vary based on the shape of the lens element 2 and/or the shape of the light receiving surface of the solar cell 1.

FIG. 3 illustrates a CPV device 300 including a backplane 3 that includes openings or holes 3f that serve as a lens cradle to support/align a lens element 2, and also includes conductive traces 4 that provide an electrical connection with the solar cell 1. In this embodiment, one or more cells 1 that include two contacts 6 accessible from the top of the cells are electrically connected to the conductive traces 4 on the underside of the backplane 3, and one or more lenses 2 are provided on the top side of the backplane 3, such that the backplane 3 extends at least partially between the lens element(s) 2 and the solar cell 1. In particular, FIG. 3 illustrates a concentrator solar cell 1, a spherical or ball lens 2 (illustrated as a glass bead), and a backplane 3 including metal (for example, copper) traces 4 on the backplane 3. The opening or hole 3f in the backplane 3 is sized and configured to support and align the ball (or other-shaped) lens 2 with the light receiving surface of the solar cell 1. A solder mask 5 may be used in some embodiments to guide the spatial positions of components during reflow of a solder connection (illustrated more generally as a cell contact 6) to the solar cell 1. An optically transparent material 7 may encapsulate the cell 1 and bond the ball lens 2 to the cell 1 and related components. A material 13 serves as a thermal interface material and/or an encapsulant on and/or surrounding the surface of the solar cell 1 opposite the backplane 3. A heat sink 14 may also be provided in contact with the thermal interface material 13 in some embodiments.

The hole or opening 3f in the backplane 3 supports and self-aligns the ball (or other-shaped) lens 2 with the light-receiving surface of the solar cell 1, and an electrical connection is provided between the backplane 3 and the cell contact 6 on the surface of the cell 1 that is adjacent the backplane 3 at edges of the opening or hole 3f. The shape of the hole or opening 3f in the backplane 3 may depend on the shape of the lens element 2 and/or the shape of the light receiving surface of the solar cell 1, and may include any shape that supports and aligns the lens element 2 with the light receiving surface, including polygonal or ellipsoidal shapes. For example, the hole or opening 3f in the backplane 3 may define a polygonal- or ellipsoidal-shaped cavity or depression therein.

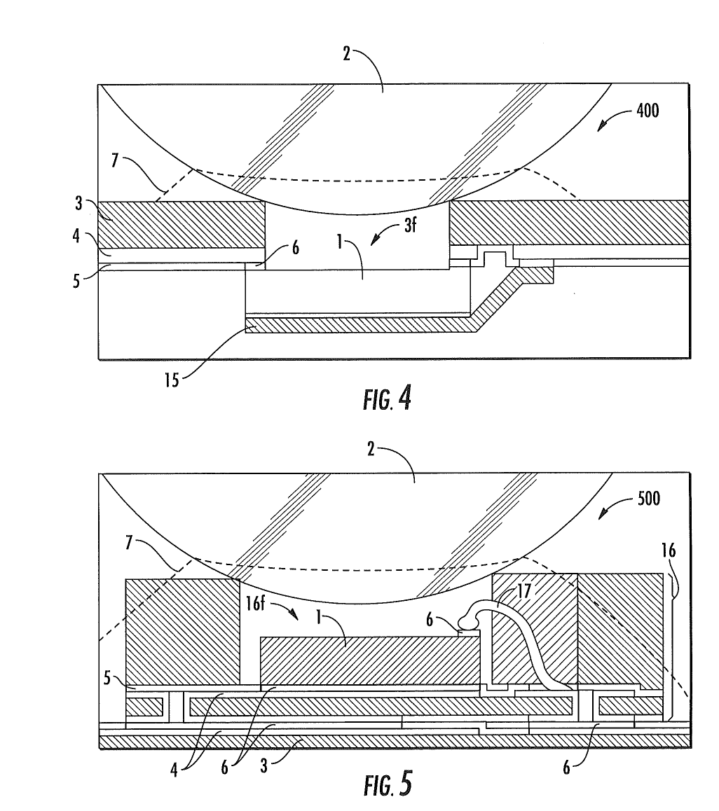

FIG. 4 illustrates a CPV device 400 including a backplane 3 that includes openings or holes 3f that serve as a lens cradle to support/align a lens element 2, and also includes conductive elements 4 and 15 that provide an electrical connection with the solar cell 1. In this embodiment, one contact 6 accessible from the top side or surface of the cell 1 and one contact 6 accessible from the bottom side or surface of the cell 1 are electrically connected to the traces 4 on the underside of the backplane 3, while one or more lenses 2 are provided on the top side of the backplane 3, such that the backplane 3 extends at least partially between the lens element(s) 2 and the solar cell 1. Electrical contact between the contact 6 on the bottom of the cell 1 and the backplane 3 is provided by a conductive surface-mount lead frame 15. In particular, FIG. 4 illustrates a concentrator solar cell 1, a spherical or ball lens 2 (illustrated as a glass bead), and a backplane 3 including metal (for example, copper) traces 4 on the backplane 3. The opening or hole 3f in the backplane 3 is sized and configured to support and align the ball (or other-shaped) lens 2 with the light receiving surface of the solar cell 1. A solder mask 5 may be used in some embodiments to guide the spatial positions of components during reflow of a solder connection (illustrated more generally as a cell contact 6) to the solar cell 1. An optically transparent material 7 may encapsulate the cell 1 and bond the ball lens 2 to the cell 1 and related components. A surface mount lead-frame interconnection structure 15 provides an electrical connection between the backplane 3 and the contact 6 on the surface of the cell 1 opposite the backplane 3.

The hole or opening 3f in the backplane 3 supports and self-aligns the ball (or other-shaped) lens 2 with the solar cell 1, and an electrical connection is provided between the backplane 3 and the cell contact 6 on the surface of the cell 1 that is adjacent the backplane 3 at edges of the opening or hole 3f by the traces 4. Another electrical connection is provided between the backplane 3 and the cell contact 6 on the surface of the cell 1 that is opposite the backplane 3 by the conductive surface-mount lead frame 15. As similarly discussed with reference to FIG. 4, the shape of the hole or opening 3f in the backplane 3 may be based on the shape of the lens element 2 and/or the shape of the light receiving surface of the solar cell 1, and may include any shape that supports and aligns the lens element 2 with the light receiving surface, including polygonal or ellipsoidal shapes. For example, the hole or opening 3f in the backplane 3 may define a polygonal- or ellipsoidal-shaped cavity or depression therein.

Further embodiments of the present invention include structures that may provide a lens cradle and electrical contact to a solar cell in a separate or non-simultaneous manner.

FIG. 5 illustrates a CPV device 500 including a surface-mountable, multilayer printed wiring board interposer 16 that includes a lens support frame or cradle structure. In this embodiment, each interposer 16 may include fiber-reinforced resin materials, alumina ceramic materials, other ceramic materials, metals, or combinations of these materials. For example, some embodiments of the surface mountable, multilayer printed wiring board interposer 16 may include an alumina substrate with metallized through-substrate vias, with filled acrylic photo-definable materials built on top of the surface of the ceramic substrate to form a lens cradle.

In particular, FIG. 5 illustrates a concentrator solar cell 1, a spherical or ball lens 2 (illustrated as a glass bead), and a backplane 3 including metal (e.g. copper) traces 4 on the backplane 3. A solder mask 5 may be used to guide the spatial positions of components during reflow of a solder connection (illustrated more generally as a cell contact 6) to the solar cell 1. An optically transparent material 7 may encapsulate the cell 1 and bond the ball (or other-shaped) lens 2 to the cell 1 and related components. The solar cell 1 is provided on a surface-mountable, multilayer printed wiring board interposer 16 that supports and self-aligns the ball lens 2 with the light receiving surface of the solar cell 1 to concentrate light thereon. As such, the multilayer printed wiring board interposer 16 includes the cell 1 on a surface thereof that is between the cell 1 and the backplane 3. The multilayer printed wiring board interposer 16 also includes features protruding from the surface thereof to support the lens 2, which define a cavity or opening 16f that exposes the light receiving surface of the solar cell 1. A wire bond 17, such as a gold, aluminum, and/or copper wire bond, electrically connects a contact 6 on a surface of the cell 1 opposite the backplane 3 to a contact 6 on the multilayer printed wiring board interposer 16, which provides an electrical connection to the conductive traces 4 on the backplane.

The shape of the features of the multilayer printed wiring board interposer 16 that support the lens element 2 may depend on the shape of the lens element 2 and/or the light receiving area of the solar cell 1, and may include any shape that supports and aligns the lens element 2 with the light receiving surface, including polygonal or ellipsoidal shapes. The opening 16f in the multilayer printed wiring board interposer 16 may likewise define a polygonal- or ellipsoidal-shape, based on the shape of the lens element 2 and/or the shape of the light receiving surface of the solar cell 1.

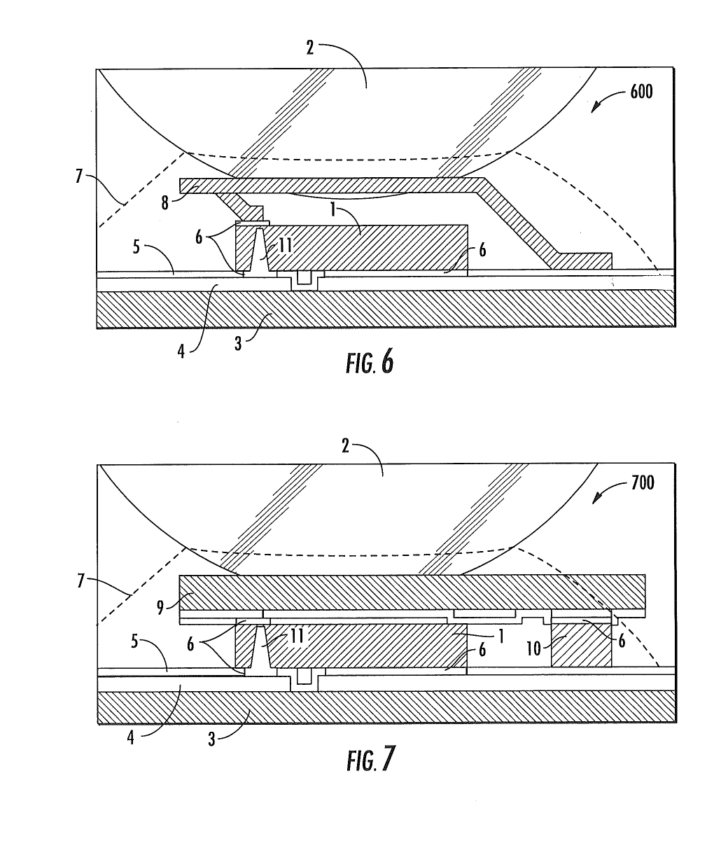

FIG. 6 depicts a CPV device 600 including a surface-mountable, multi-junction concentrator solar cell 1 that includes one or more through-wafer vias 11 (also referred to herein as through-substrate interconnects or through-substrate vias TSVs) to electrically connect the top terminal 6 of the solar cell 1 to a backplane 3 (or interposer) in a surface mount operation. FIG. 6 further depicts a surface mountable lead frame lens support frame or cradle 8, which may support the lens 2 in a manner similar to that shown in FIG. 1A, but does not provide an electrical connection between the top terminal 6 and the traces 4 on the backplane 3.

In particular, FIG. 6 illustrates a concentrator solar cell 1, a spherical or ball lens 2 (illustrated as a glass bead), and a backplane 3 including metal (for example, copper) traces 4 on the backplane 3. A solder mask 5may be used in some embodiments to guide the spatial positions of components during reflow of a solder connection (illustrated more generally as a contact 6) to the solar cell 1. An optically transparent material 7 may encapsulate the cell 1 and bond the ball or other-shaped lens 2 to the cell 1 and related components. A through-wafer via or interconnect 11 having insulated sidewalls (also referred to as a through-substrate via TSV) extends into or through the solar cell 1 from the surface adjacent the backplane 3 toward the surface opposite the backplane 3. The via 11 electrically connects the contact 6 on the surface of the cell 1 opposite the backplane 3 to the conductive trace 4 on the backplane 3. In some embodiments where the solar cell 1 includes a light reactive layer on a wafer (such as a growth substrate) mounted on the backplane 3, the via 11 extends through the wafer to electrically connect a top contact 6 on or adjacent the light reactive layer to an electrical node on a back-side of the wafer of the solar cell 1. The surface mountable lead frame lens cradle 8 supports and self-aligns the ball lens 2 with the solar cell 1 to concentrate light thereon.

As similarly described above with reference to FIGS. 1A-1D, the conductive lens support frame 8 includes a metal frame or periphery that defines a polygonal opening or cavity therein that exposes the light receiving surface of the solar cell 1, as well as “legs” that extend from the metal frame to contact the backplane 3 and the solar cell 1 via respective “foot” portions. One or more of the members of the support frame 8 may be formed from a single conductive layer, or may be separately formed and assembled. Also, the shape of the conductive lens support frame 8 and/or the opening therein may depend on the shape of the lens element 2 and/or the shape of the light receiving surface of the solar cell 1, and may include any shape that supports and aligns the lens element 2 with the light receiving surface. For example, the lens support frame may have a polygonal or ellipsoidal shape, and may include a polygonal- or ellipsoidal-shaped cavity or opening therein.

FIG. 7 illustrates a CPV device 700 including a surface-mountable, multi-junction concentrator solar cell 1 that includes one or more through-wafer vias (also referred to herein as through-substrate interconnects or through-substrate vias TSVs) 11 to electrically connect the top terminal 6 of the solar cell to a backplane 3 (or interposer) in a surface mount operation. FIG. 7 further depicts a surface mountable lens cradle 9 that includes a printed wiring board, which may support the lens 2 in a manner similar to that shown in FIG. 2, but does not provide an electrical connection between the top terminal 6 and the traces 4 on the backplane 3.

In particular, FIG. 7 illustrates a concentrator solar cell 1, a spherical or ball lens 2 (illustrated as a glass bead), and a backplane 3 including metal (e.g. copper) traces 4 on the backplane 3. A solder mask 5 may be used in some embodiments to guide the spatial positions of components during reflow of a solder connection (illustrated more generally as a contact 6) to the solar cell 1. An optically transparent material 7 may encapsulate the cell 1 and bond the ball (or other-shaped) lens 2 to the cell 1 and related components. A through-wafer via 11 having insulated sidewalls (also referred to as a through-substrate via TSV) extends into or through the solar cell 1 from the surface adjacent the backplane 3 toward the surface opposite the backplane 3. The via 11 electrically connects the contact 6 on the surface of the cell 1 opposite the backplane 3 to the conductive trace 4 on the backplane 3. The surface mountable printed wiring board lens cradle 9 supports and self-aligns the ball (or other-shaped) lens 2 with the light receiving surface of the solar cell 1 to concentrate light thereon. A conductive stud 10 electrically connects to the printed wiring board lead frame 9 but does not provide an electrical connection to the backplane 3 in the embodiment illustrated.

The shape of the printed wiring board lens support frame 9 and/or the conductive traces thereon may depend on the shape of the lens element 2 and/or the shape of the light receiving surface of the solar cell 1, and may include any shape that supports and aligns the lens element 2 with the light receiving surface, including polygonal or ellipsoidal shapes. The printed wiring board lens support frame 9 also defines a polygonal- or ellipsoidal-shaped cavity or depression therein, which may also vary based on the shape of the lens element 2 and/or the shape of the light receiving surface of the solar cell 1.

The present invention has been described above with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. In no event, however, should “on” or “directly on” be construed as requiring a layer to cover an underlying layer.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As used in the description of the invention and the appended claims, the singular forms “a”, “an ” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, the regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. It will be further understood that terms, such as those defined in commonly used dictionaries, should be interpreted as having a meaning that is consistent with their meaning in the present specification and in the context of the relevant art and will not be interpreted in an idealized or overly formal sense unless expressly so defined herein. All publications, patent applications, patents, and other references mentioned herein are incorporated by reference in their entireties.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments of the present invention described herein, and of the manner and process of making and using them, and shall support claims to any such combination or subcombination.

In the specification, there have been disclosed embodiments of the invention and, although specific terms are employed, they are used in a generic and descriptive sense only and not for purposes of limitation.

That which is claimed:

1. A concentrator-type photovoltaic (CPV) receiver, comprising:
a solar cell on a backplane substrate, the solar cell including a light receiving surface having a conductive terminal thereon;
a conductive lens support frame on the solar cell, the support frame having an opening therein that exposes the light receiving surface of the solar cell to incident light, wherein the support frame is electrically connected to the conductive terminal on the light receiving surface and to an electrical node on the substrate; and
a lens element on the support frame opposite the light receiving surface of the solar cell, the support frame supporting and aligning the lens element with the light receiving surface.

2. The CPV receiver of claim 1, further comprising:
a solder connection between the support frame and the conductive terminal and/or the electrical node on the substrate, wherein the support frame is configured to be self-aligned by reflow of the solder connection to align the lens element with the solar cell.

3. The CPV receiver of claim 1, wherein the support frame aligns the lens element such that a center thereof is aligned with a center of the solar cell.

4. The CPV receiver of claim 3, wherein the lens element comprises a spherical lens element, and wherein the support frame includes features for supporting and self-aligning the spherical lens element.

5. The CPV receiver of claim 1, wherein the support frame is a conductive metal frame.

6. The CPV receiver of claim 1, wherein the support frame is a printed wiring board including conductive traces thereon.

7. The CPV receiver of claim 1, wherein the support frame comprises a portion of the backplane substrate including conductive traces thereon, wherein the backplane substrate extends at least partially between the solar cell and the lens element.

8. The CPV receiver of claim 7, wherein the conductive terminal comprises a first conductive terminal, and further comprising:
a conductive lead frame electrically connecting a second conductive terminal on a surface of the solar cell opposite the light receiving surface to the substrate.

9. The CPV receiver of claim 1, wherein the support frame is a multi-layer printed wiring board interposer including the solar cell on a surface thereof, wherein the printed wiring board interposer extends between the solar cell and the backplane substrate.

10. The CPV receiver of claim 1, further comprising:
a conductive through-wafer via having insulated sidewalls extending into the solar cell from a mounting surface of the solar cell on the substrate toward the light receiving surface, wherein the via electrically connects the conductive terminal on the light receiving surface to the electrical node on the substrate.

11. A concentrator-type photovoltaic (CPV) device, comprising:
a solar cell on a substrate, the solar cell including a light receiving surface and a conductive terminal;
a conductive lens support frame on the solar cell exposing the light receiving surface thereof and electrically connecting the conductive terminal to a contact on the substrate; and
a lens element positioned over the light receiving surface by the support frame.

12. The device of claim 11, wherein the lens support frame includes an opening therein that exposes the light receiving surface.

13. The device of claim 12, wherein the support frame aligns the lens element with a center of the light receiving surface.

14. The device of claim 13, wherein the light receiving surface has an area of about 4 mm² or less.

15. The device of claim 14, wherein the lens element comprises a spherical lens element.

16. The device of claim 15, wherein the lens element extends at least partially into the opening.

17. The device of claim 11, wherein the support frame comprises a conductive metal frame.

18. The device of claim 11, wherein the support frame comprises a printed wiring board including conductive traces thereon.

19. The device of claim 11, wherein the support frame comprises a portion of the backplane substrate including conductive traces thereon.

20. A process for fabricating a concentrator-type photovoltaic (CPV) receiver on a backplane substrate, the process comprising:
mounting a solar cell to a surface of the substrate, the solar cell including a light receiving surface having a conductive terminal thereon;
mounting a conductive lens support frame onto the solar cell, wherein the support frame electrically connects the conductive terminal of the solar cell to an electrical node on the substrate, the support frame having an opening therein that exposes the light receiving surface of the solar cell to incident light; and
placing a lens element on the support frame opposite the light receiving surface of the solar cell, the support frame supporting and aligning the lens element with the light receiving surface.

21. The process of claim 20, wherein the support frame is mounted using a solder connection between the support frame and the conductive terminal and/or between the support frame and the electrical node on the substrate, and further comprising:
reflowing the solder connection to align the opening in the support frame with the light receiving surface of the solar cell.

22. The process of claim 20, wherein the lens element comprises a spherical lens element, and wherein the support frame includes features that support and self-align the spherical lens element.

23. The process of claim 20, wherein the support frame is a conductive metal frame, and wherein mounting the support frame comprises:
surface-mounting the support frame onto the light receiving surface of the solar cell to contact the conductive terminal thereon.

24. The process of claim 20, wherein the support frame is a printed wiring board including conductive traces thereon, and wherein mounting the support frame comprises:
surface-mounting the support frame onto the light receiving surface of the solar cell to contact the conductive terminal thereon.

25. The process of claim 20, wherein the support frame is a multi-layer printed wiring board interposer, wherein mounting the solar cell comprises mounting the solar cell on a surface of the printed wiring board interposer, and wherein mounting the support frame comprises surface-mounting the printed wiring board interposer on the surface of the substrate.
